(19) United States
(12) Patent Application Publication
(10) Pub. No.: US 2020/0212151 A1
(43) Pub. Date: Jul. 2, 2020

(54) FLEXIBLE DISPLAY PANEL AND FLEXIBLE DISPLAY DEVICE

(71) Applicant: Wuhan China Star Optoelectronics Semiconductor Display Technology Co., Ltd., Wuhan (CN)

(72) Inventor: Xiaoxia ZHANG, Wuhan (CN)

(73) Assignee: Wuhan China Star Optoelectronics Semiconductor Display Technology Co., Ltd., Wuhan (CN)

(21) Appl. No.: 16/349,616

(22) PCT Filed: Mar. 18, 2019
(86) PCT No.: PCT/CN2019/078560

§ 371 Date: May 14, 2019

(30) Foreign Application Priority Data
Nov. 26, 2018 (CN) 201811416509.9

(51) Int. Cl. H01L 27/32; H01L 51/00; G06F 1/16; G09F 9/30

(52) U.S. Cl. CPC H01L 27/3262; H01L 51/0097; G09F 9/301; G06F 1/1652; H01L 27/3276

(57) ABSTRACT

A flexible display panel and a flexible device are provided. At least one groove or at least one protrusion is disposed between two adjacent signal lines of a first metal layer of an edge of an organic layer and a total length of the edge of the organic layer between the two adjacent signal lines is increased, so that a continuous residual second metal layer between the two adjacent signal lines is reduced. A short circuit problem existed in the signal lines of the first metal layer in a laminated structure of the first metal layer/the organic layer/the second metal layer is avoided. Meanwhile, a distance between the two adjacent signal lines is not increased, and thus a signal line layout of the first metal layer is not affected. Therefore, the stability and reliability of the flexible display panel are effectively improved.

### BACKGROUND OF INVENTION

### Field of Invention

The present invention relates to a field of display panels, and more particularly, to a flexible display panel with a high panel manufacturing yield and a flexible display device.

### Description of Prior Art

Flexible display devices are new generation of display products. The flexible display devices have become more and more popular because of being ultra-light, being ultra-thin, high resolution, quick response times, flexibility, and portability. With continuous updating of display technologies, flexible display panels are developing toward being thinner, narrow frames, and borderless features, and a bending area is the core technology of narrow/borderless frames.

In current flexible display panels, there is usually a laminated structure of a first metal layer/an organic layer/a second metal layer, and the first metal layer and the second metal layer are generally used for transmitting signals. However, in general, the organic layer is relatively thick, and an edge has a steep slope. When the second metal layer is etched, there is still a continuous residual second metal layer. If the edge of the organic layer extends across two signal lines of the first metal layer, and the continuous residual second metal layer is generated, a short circuit between the signal lines of the first metal layer is occurred, which causes the panels to fail.

Referring to FIG. 1A and FIG. 1B, FIG. 1A is a two-dimensional top view of a first metal layer and an organic stacked layer of a flexible display panel in prior art, and FIG. 1B is a two-dimensional top view of a residual second metal layer at an edge of the organic layer of the flexible display panel in the prior art. In general, a greater distance between two adjacent signal lines 111 of the first metal layer 11, a lower probability that a second metal layer 12 on the organic layer 13 remains between the two adjacent signal lines 111. In the prior art, the distance between adjacent signal lines 111 of the first metal layer 11 (i.e., “a” value in the figures) is generally increased to reduce the probability of a short circuit. In general, the “a” value is greater than or equal to 20 μm. However, if the signal lines of the first metal layer 11 are more, such a design occupies a space and makes a layout of the first metal layer 11 more difficult.

Therefore, how to avoid the problem of a short circuit between the signal lines of the first metal layer caused by the residual second metal layer in the laminated structure of the first metal layer/organic layer/second metal layer is a problem that needs to be solved in the development process for the flexible display and narrow frame/borderless panel technologies.

### SUMMARY OF INVENTION

One object of the present invention is to provide a flexible display panel and a flexible display device, which can avoid a short circuit problem between two signal lines of the first metal layer in a laminated structure of the first metal layer/organic layer/second metal layer caused by the residual second metal layer. Accordingly, the stability and reliability of the flexible display panel are effectively improved.

In order to achieve the above object of the present invention, a flexible display panel provided by one embodiment of the present invention comprises a first metal layer, an organic layer, and a second metal layer stacked in sequence, wherein an edge of the organic layer extends across a plurality of signal lines of the first metal layer, and at least one groove and/or at least one protrusion is disposed between two adjacent signal lines of the first metal layer of the edge of the organic layer and a total length of the edge of the organic layer between the two adjacent signal lines is increased, so that there is no continuous residual second metal layer between the adjacent two signal lines.

The advantage is that a total length of the edge of the organic layer between the two adjacent signal lines is increased because of a groove or a protrusion is disposed between two adjacent signal lines of the edge of the organic layer. Thus, a continuous residual second metal layer can be effectively reduced, and a short circuit caused by the residual second metal layer is avoided. Meanwhile, a distance between the two adjacent signal lines is not increased, and thus the signal line layout of the first metal layer is not affected. Accordingly, the stability and reliability of the flexible display panel are effectively improved.

### BRIEF DESCRIPTION OF DRAWINGS

In order to more clearly illustrate embodiments or technical solutions in the present invention, the drawings used in the description of the embodiments or current technology will be briefly described below. Obviously, the drawings in the following description are merely some embodiments of the present invention. A person skilled in the art may also obtain other drawings without any creative efforts.

FIG. 1A is a two-dimensional top view of a first metal layer and an organic stacked layer of a flexible display panel in the prior art.

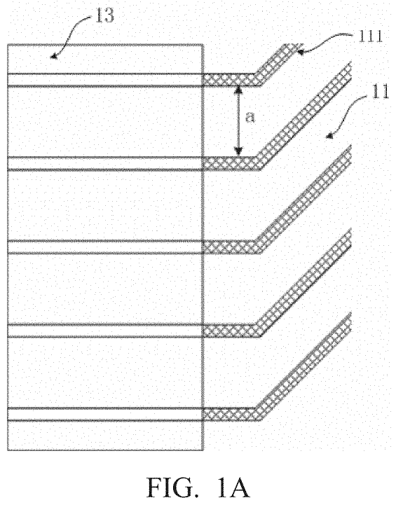

FIG. 1B is a two-dimensional top view of a residual second metal layer at an edge of the organic layer of the flexible display panel in the prior art.

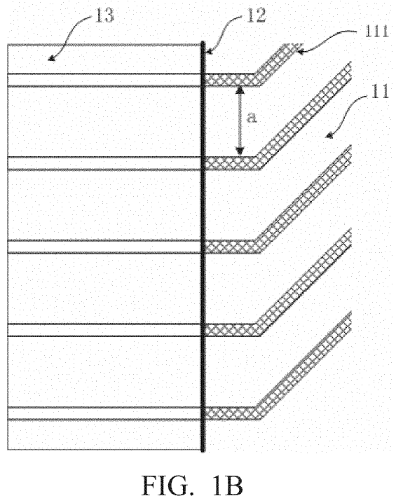

FIG. 2 is a two-dimensional top view of a first metal layer and an organic stacked layer of a flexible display panel according a first embodiment of the present invention.

FIG. 3 is a two-dimensional top view of a first metal layer and an organic stacked layer of a flexible display panel according a second embodiment of the present invention.

FIG. 4 is a two-dimensional top view of a first metal layer and an organic stacked layer of a flexible display panel according a third embodiment of the present invention.

FIG. 5 is a two-dimensional top view of a first metal layer and an organic stacked layer of a flexible display panel according a fourth embodiment of the present invention.

FIG. 6 is a two-dimensional top view of a first metal layer and an organic stacked layer of a flexible display panel according a fifth embodiment of the present invention.

### DETAILED DESCRIPTION OF PREFERRED EMBODIMENTS

The embodiments of the present invention are described in detail below, and the examples of the embodiments are illustrated in the drawings, in which the same or similar reference numerals indicate the same or similar elements or elements having the same or similar functions. The embodiments described below with reference to the drawings are used to understand the present invention, but are not to be as limiting.

The terms “first,” “second,” and “third,” etc. (if present) in the specification and claims of the present invention and the above figures are used to distinguish similar objects and are not necessarily used to describe a particular order. Or prioritization. It should be understood that the objects so described are interchangeable where appropriate. Moreover, the terms “comprise” and “include” and any variations thereof are intended to cover a non-exclusive inclusion.

In the present invention, the first feature “on” or “under” the second feature may include direct contact of the first and second features, and may also include first and second features, unless otherwise specifically defined and defined. It is not in direct contact but through additional features between them. Moreover, the first feature “above,” “upper,” and “on” the second feature includes the first feature directly above and above the second feature, or merely indicating that the first feature level is higher than the second feature. The first feature “below,” “under,” and “beneath” the second feature includes the first feature directly below and below the second feature, or merely the first feature level being less than the second feature.

The terms used in the description of the present invention are intended to describe a particular embodiment only and are not intended to illustrate the concept of the invention. Expressions used in the singular encompasses the plural forms of expression unless the context clearly dictates otherwise. In the description of the present invention, it is to be understood that the terms such as “comprise” and “include.” The possibility of one or more other features, numbers, steps, actions, or combinations thereof may be excluded. The same reference numerals in the drawings denote the same parts. Moreover, the present invention provides examples of various specific processes and materials, but one of ordinary skill in the art will recognize the use of other processes and/or the use of other materials.

In one embodiment of the present invention, a flexible display panel comprises a first metal layer, an organic layer, and a second metal layer stacked in sequence, wherein an edge of the organic layer extends across a plurality of signal lines of the first metal layer, and at least one groove and/or at least one protrusion is disposed between two adjacent signal lines of the first metal layer of the edge of the organic layer and a total length of the edge of the organic layer between the two adjacent signal lines is increased, so that there is no continuous residual second metal layer between the two adjacent signal lines.

Preferably, the total length of the edge of the organic layer between any the two adjacent signal lines is greater than or equals to 20 μm. Specifically, the total length of the edge of the organic layer between the two adjacent signal lines can be determined on a fabrication process as long as it can ensure that there is no continuous residual second metal layer between the two adjacent signal lines.

One or a plurality of grooves is disposed between two adjacent signal lines of the edge of the organic layer. When the plurality of grooves are disposed between all the two adjacent signal lines of the edge of the organic layer, the plurality of grooves are spaced apart from each other along the edge of the organic layer in a direction of a length. Preferably, the plurality of grooves are evenly distributed along the edge of the organic layer in the direction of the length, and thus the fabrication process is simplified. Each groove can be in any shapes, for example, a shape of each groove is selected from one or more of a rectangle, a triangle, a parallelogram, a trapezoid, and an arc, or a combination of any two or more. A side length of the plurality of grooves having different shapes is not limited and can be modified according to actual needs. Meanwhile, the total length of the edge of the organic layer between the two adjacent signal lines is determined on the total side length of all the grooves between the two adjacent signal lines, and the total length can be specifically determined on the fabrication process as long as it can ensure that there is no continuous residual second metal layer between the two adjacent signal lines.

Similarly, one or a plurality of protrusions is disposed between two adjacent signal lines of the edge of the organic layer. When the plurality of protrusions are disposed between all the two adjacent signal lines of the edge of the organic layer, the plurality of protrusions are spaced apart from each other along the edge of the organic layer in a direction of a length. Preferably, the plurality of protrusions are evenly distributed along the edge of the organic layer in the direction of the length, and thus the fabrication process is simplified. Each groove can be in any shape, for example, the shape of each groove is selected from one or more of a rectangle, a triangle, a parallelogram, a trapezoid, and an arc, or a combination of any two or more. A side length of the plurality of protrusions having different shapes is not limited and can be modified according to actual needs. Meanwhile, the total length of the edge of the organic layer between the two adjacent signal lines is determined on the total side length of all the protrusions between the two adjacent signal lines, and the total length can be specifically determined on the fabrication process as long as it can ensure that there is no continuous residual second metal layer between the two adjacent signal lines.

At least one groove and at least one protrusion can be further disposed between two different adjacent signal lines of the edge of the organic layer at a same time. For example, one or more grooves are disposed between two adjacent signal lines of the edge of the organic layer, and one or more protrusions are disposed between two adjacent signal lines of the edge of the organic layer. A number of the grooves and the protrusions may be the same or different. A plurality of grooves/a plurality of protrusions can be distributed, preferably evenly distributed, at intervals between the two adjacent lines along the edge of the organic layer in a direction of a length.

In the flexible display panel according one embodiment of the present invention, when an edge of the organic layer extends across a plurality of signal lines of a first metal layer, at least one groove and/or at least one protrusion is disposed between two adjacent signal lines of the edge of the organic layer and thereby a total a total length of the edge of the organic layer between the two adjacent signal lines is increased. Due to the at least one groove and/or the at least one protrusion, a total length of the edge of the organic layer between the two adjacent signal lines is long enough, so that a continuous residual second metal layer between the two adjacent signal lines can be effectively reduced. Consequently, a short circuit between the two adjacent signal lines is avoided. Meanwhile, a distance between the two adjacent signal lines is not increased, and thus a signal line layout of the first metal layer is not affected. Therefore, the stability and reliability of the flexible display panel are effectively improved.

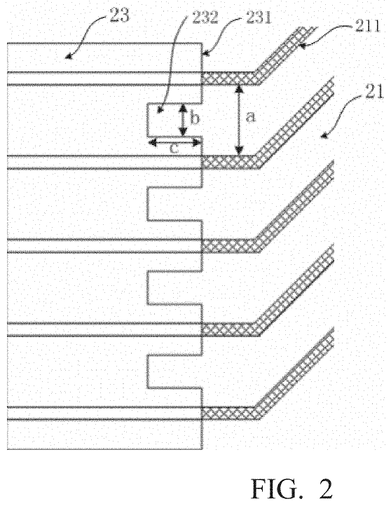

Referring to FIG. 2, it is a two-dimensional top view of a first metal layer and an organic stacked layer of a flexible display panel according a first embodiment of the present invention. The flexible display panel comprises a first metal layer 21, an organic layer 23 which may be made of a transparent organic material, and a second metal layer (not shown) stacked in sequence, an edge 231 of the organic layer 23 extends across a plurality of signal lines 211 of the first metal layer 21, and a rectangular groove 232 is disposed between two adjacent signal lines 211 of the first metal layer 21 of the edge 231 of the organic layer 23 and thereby a total length of the edge 231 of the organic layer 23 between the two adjacent signal lines 211 is increased, so that there is no continuous residual second metal layer between the two adjacent signal lines 211.

That is, in the embodiment of the present invention, the edge 231 of the organic layer 23 extends across the plurality of signal lines 211 of the first metal layer 21, and the rectangular groove 232 is disposed between the two adjacent signal lines 211 of the edge 231 of the organic layer 23. The width and length of the rectangular groove 232 are not limited and can be determined according to actual needs and fabrication processes. It is only necessary to ensure that there is no continuous residual second metal layer remaining in the total length of the edge of the organic layer of 2*c+b, wherein c is a length of the rectangular groove 232 and b is a width of the rectangular groove 232. In another embodiment of the present invention, a shape of the groove may be any one or more of a triangle, a parallelogram, a trapezoid, and an arc.

The groove is disposed between all the two adjacent signal lines of the edge of the organic layer due to improving the edge of the organic layer. Therefore, the total length of the edge of the organic layer between the two adjacent signal lines is increased, so that the continuous residual second metal layer can be effectively reduced, and a short circuit caused by the residual second metal layer is avoided. Meanwhile, a distance between the two adjacent signal lines is not increased, and thus the signal line layout of the first metal layer is not affected. Accordingly, the stability and reliability of the flexible display panel are effectively improved.

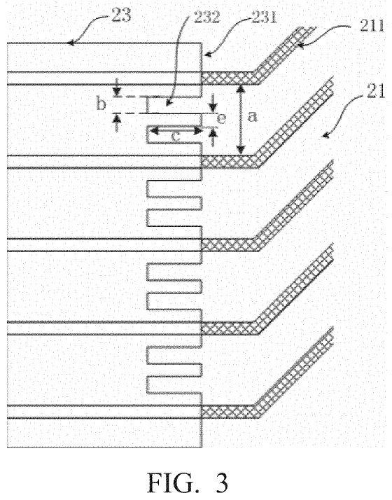

Referring to FIG. 3, it is a two-dimensional top view of a first metal layer and an organic stacked layer of a flexible display panel according a second embodiment of the present invention. The difference from the first embodiment shown in FIG. 2 is that, in second embodiment of the present invention, the edge 231 of the organic layer 23 extends across the plurality of signal lines 211 of the first metal layer 21, and two rectangular grooves 232 are disposed between the two adjacent signal lines 211 of the edge 231 of the organic layer 23. The width and length of the rectangular grooves 232 are not limited and can be determined according to actual needs. It is only necessary to ensure that there is no continuous residual second metal layer remaining in the organic layer which has a total length of the edge of 4*c+2*b+e, wherein c is a length of the rectangular groove 232, b is a width of the rectangular groove 232, and e is a distance between the two rectangular grooves 232. In another embodiment of the present invention, a shape of the groove may be any one or more of a triangle, a parallelogram, a trapezoid, and an arc.

In another embodiment of the present invention, a plurality of rectangular grooves 232 are disposed between the two adjacent signal lines 211 of the edge 231 of the organic layer 23, and a total length of the edge of the organic layer is 2m*c+m*b+n*e, wherein m and n are determined on the number of rectangular grooves. Similarly, the width and length of all rectangular grooves are not limited and can be determined according to actual needs and a fabrication process. It is only necessary to ensure that there is no continuous residual second metal layer remaining in the organic layer which has a total length of the edge of 2m*c+m*b+n*e. The plurality of rectangular grooves 232 are spaced apart along the edge 231 of the organic layer in a direction of a length. Preferably, the plurality of rectangular grooves 232 are evenly distributed along the edge 231 of the organic layer 23 in a direction of a length, and thus the fabrication process is simplified.

In the embodiment of the present invention, the total length of the edge of the organic layer between the two adjacent signal lines is increased due to improving the edge of the organic layer, so that continuous residual second metal layer between the two adjacent signal lines is reduced. A short circuit problem existed in the signal lines of the first metal layer, which is caused by the residual second metal layer, is avoided. Meanwhile, a distance between the two adjacent signal lines is not increased, and thus the signal line layout of the first metal layer is not affected. Accordingly, the stability and reliability of the flexible display panel are effectively improved.

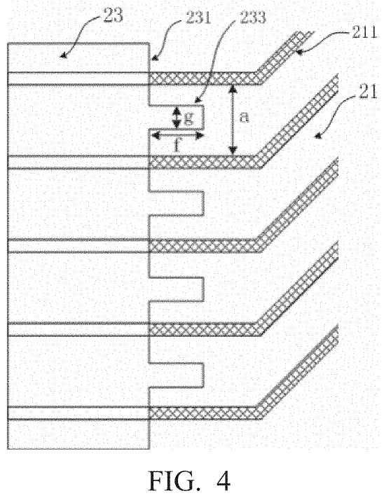

Referring to FIG. 4, it is a two-dimensional top view of a first metal layer and an organic stacked layer of a flexible display panel according a third embodiment of the present invention. The flexible display panel comprises the first metal layer 21, an organic layer 23 which may be made of a transparent organic material, and a second metal layer (not shown) stacked in sequence, an edge 231 of the organic layer 23 extends across a plurality of signal lines 211 of the first metal layer 21, and a rectangular protrusion 233 is disposed between the two adjacent signal lines 211 of the first metal layer 21 of the edge 231 of the organic layer 23 and thereby a total length of the edge 231 of the organic layer 23 between the two adjacent signal lines 211 is increased, so that there is no continuous residual second metal layer between the two adjacent signal lines 211.

That is, in the embodiment of the present invention, the edge 231 of the organic layer 23 extends across the plurality of signal lines 211 of the first metal layer 21, and the rectangular protrusion 233 is disposed between the two adjacent signal lines 211 of the edge 231 of the organic layer 23. The width and length of the rectangular protrusion 233 are not limited and can be determined according to actual needs and fabrication processes. It is only necessary to ensure that there is no continuous residual second metal layer remaining in the organic layer which has a total length of the edge of 2*f+g, wherein f is a length of the rectangular protrusion 233 and g is a width of the rectangular protrusion 233. In another embodiment of the present invention, a shape of the rectangular protrusion may be any one or more of a triangle, a parallelogram, a trapezoid, and an arc.

A protrusion is disposed between all the two adjacent signal lines of the edge of the organic layer due to improving an edge of the organic layer. Therefore, a total length of the edge of the organic layer between the two adjacent signal lines is increased, so that a continuous residual second metal layer can be effectively reduced, and a short circuit caused by the residual second metal layer is avoided. Meanwhile, a distance between the two adjacent signal lines is not increased, and thus the signal line layout of the first metal layer is not affected. Accordingly, the stability and reliability of the flexible display panel are effectively improved.

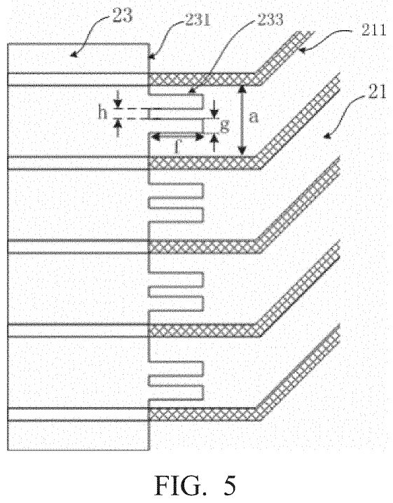

Referring to FIG. 5, it is a two-dimensional top view of a first metal layer and an organic stacked layer of a flexible display panel according a fourth embodiment of the present invention. The difference from the third embodiment shown in FIG. 4 is that, in fourth embodiment of the present invention, an edge 231 of the organic layer 23 extends across a plurality of signal lines 211 of the first metal layer 21, and two rectangular protrusions 233 are disposed between the two adjacent signal lines 211 of the edge 231 of the organic layer 23. The width and length of the rectangular protrusions 233 are not limited and can be determined according to actual needs. It is only necessary to ensure that there is no continuous residual second metal layer remaining in the organic layer which has a total length of the edge of 4*f+2*g+h, wherein f is a length of the rectangular groove 232, g is a width of the rectangular protrusion 233, and h is a distance between the two rectangular protrusions 233. In another embodiment of the present invention, a shape of the protrusion may be any one or more of a triangle, a parallelogram, a trapezoid, and an arc.

In another embodiment of the present invention, a plurality of rectangular protrusions 233 are disposed between the two adjacent signal lines 211 of the edge 231 of the organic layer 23, and a total length of the edge of the organic layer is 2m*f+m*g+n*h, wherein m and n are determined on a number of rectangular protrusions. Similarly, the width and length of all rectangular protrusions are not limited and can be determined according to actual needs and a fabrication process. It is only necessary to ensure that there is no continuous residual second metal layer remaining in the organic layer which has a total length of the edge of 2m*f+m*g+n*h. The plurality of rectangular protrusions 233 are spaced apart along the edge 231 of the organic layer in a direction of a length. Preferably, the plurality of rectangular protrusions 233 are evenly distributed along the edge 231 of the organic layer 23 in a direction of a length, and thus the fabrication process is simplified.

In the embodiment of the present invention, a total length of the edge of the organic layer between the two adjacent signal lines is increased due to improving the edge of the organic layer, so that continuous residual second metal layer between the two adjacent signal lines is reduced. A short circuit problem existed in the signal line of the first metal layer, which is caused by the residual second metal layer, is avoided. Meanwhile, a distance between the two adjacent signal lines is not increased, and thus the signal line layout of the first metal layer is not affected. Accordingly, the stability and reliability of the flexible display panel are effectively improved.

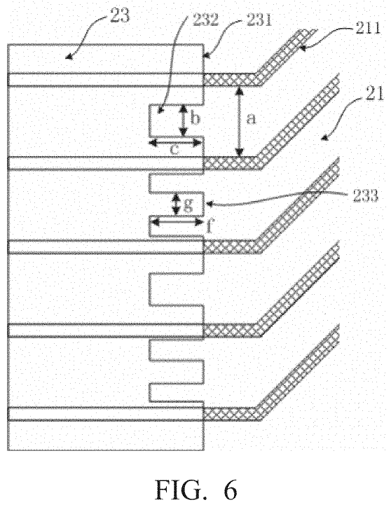

Referring to FIG. 6, it is a two-dimensional top view of a first metal layer and an organic stacked layer of a flexible display panel according a fifth embodiment of the present invention. The flexible display panel comprises the first metal layer 21, an organic layer 23 which may be made of a transparent organic material, and a second metal layer (not shown) stacked in sequence, an edge 231 of the organic layer 23 extends across a plurality of signal lines 211 of the first metal layer 21, and a rectangular groove 232 or a rectangular protrusion 233 is disposed between two adjacent signal lines 211 of the first metal layer 21 of the edge 231 of the organic layer 23 and thereby a total length of the edge 231 of the organic layer 23 between the two adjacent signal lines 211 is increased, so that there is no continuous residual second metal layer between the two adjacent signal lines 211.

That is, in the embodiment of the present invention, the edge 231 of the organic layer 23 extends across the plurality of signal lines 211 of the first metal layer 21, and the rectangular groove 232 or the rectangular protrusion 233 is disposed between the two adjacent signal lines 211 of the edge 231 of the organic layer 23. The width and length of the rectangular groove 232 and the rectangular protrusion 233 are not limited and can be determined according to actual needs and fabrication processes. It is only necessary to ensure that there is no continuous residual second metal layer remaining in the organic layer which has a total length of the edge of 2*c+b or 2*f+g, wherein c is a length of the rectangular groove 232, b is a width of the rectangular groove 232, f is a length of the rectangular protrusion 233, and g is a width of the rectangular protrusion 233. In another embodiment of the present invention, a shape of the groove/protrusion may be any one or more of a triangle, a parallelogram, a trapezoid, and an arc.

In another embodiment of the present invention, a plurality of rectangular grooves 232 or rectangular grooves 232 are disposed between the two adjacent signal lines 211 of the edge 231 of the organic layer 23, and a total length of the edge of the organic layer is 2m*c+m*b+n*e or 2m*f+m*g+n*h, wherein m and n are determined on the number of rectangular grooves/rectangular protrusions. Similarly, the width and length of all the rectangular grooves/rectangular protrusions are not limited and can be determined according to actual needs and a fabrication process. It is only necessary to ensure that there is no continuous residual second metal layer remaining in the organic layer. The plurality of grooves/protrusions are distributed at intervals along the edge of the organic layer in a direction of a length. Preferably, the plurality of grooves/protrusions are evenly distributed along the edge of the organic layer in a direction of a length.

In the embodiment of the present invention, the total length of the edge of the organic layer between the two adjacent signal lines is increased due to improving the edge of the organic layer, so that the continuous residual second metal layer between the two adjacent signal lines is reduced. A short circuit problem existed in the signal line of the first metal layer, which is caused by the residual second metal layer, is avoided. Meanwhile, a distance between the two adjacent signal lines is not increased, and thus the signal line layout of the first metal layer is not affected. Accordingly, the stability and reliability of the flexible display panel are effectively improved.

Furthermore, in one embodiment of the present invention, a flexible display device is provided. The above-mentioned flexible display panel according to the embodiment of the present invention is used for the flexible display device. A total length of the edge of the organic layer between the two adjacent signal lines is increased due to improving the edge of the organic layer, so that the continuous residual second metal layer between the two adjacent signal lines is reduced. The short circuit problem existed in the signal line of the first metal layer, which is caused by the residual second metal layer, is avoided. Meanwhile, a distance between the two adjacent signal lines is not increased, and thus the signal line layout of the first metal layer is not affected. Accordingly, the stability and reliability of the flexible display panel are effectively improved.

The subject matter of the present application can be manufactured and used in the industry, and it has an industrial applicability.

What is claimed is:

1. A flexible display panel, comprising a first metal layer, an organic layer, and a second metal layer stacked in sequence, wherein an edge of the organic layer extends across a plurality of signal lines of the first metal layer, and at least one groove and/or at least one protrusion is disposed between two adjacent signal lines of the first metal layer of the edge of the organic layer and a total length of the edge of the organic layer between the two adjacent signal lines is increased, so that there is no continuous residual second metal layer between the two adjacent signal lines.

2. The flexible display panel according to claim 1, wherein a shape of the at least one groove is selected from one or more of a rectangle, a triangle, a parallelogram, a trapezoid, and an arc.

3. The flexible display panel according to claim 1, wherein a shape of the at least one protrusion is selected from one or more of a rectangle, a triangle, a parallelogram, a trapezoid, and an arc.

4. The flexible display panel according to claim 1, wherein a plurality of grooves are disposed between all the two adjacent signal lines of the edge of the organic layer.

5. The flexible display panel according to claim 4, wherein the plurality of grooves are evenly distributed along the edge of the organic layer in a direction of a length.

6. The flexible display panel according to claim 1, wherein a plurality of protrusions are disposed between all the two adjacent signal lines of the edge of the organic layer.

7. The flexible display panel according to claim 6, wherein the plurality of protrusions are evenly distributed along the edge of the organic layer in a direction of a length.

8. The flexible display panel according to claim 1, wherein the total length of the edge of the organic layer between any the two adjacent signal lines is greater than or equal to 20 μm.

9. A flexible display device, comprising a flexible display panel, wherein the flexible display panel comprises a first metal layer, an organic layer, and a second metal layer stacked in sequence, an edge of the organic layer extends across a plurality of signal lines of the first metal layer, and at least one groove and/or at least one protrusion is disposed between two adjacent signal lines of the first metal layer of the edge of the organic layer and thereby a total length of the edge of the organic layer between the two adjacent signal lines is increased, so that there is no continuous residual second metal layer between the two adjacent signal lines.

10. The flexible display device according to claim 9, wherein a shape of the at least one groove is selected from one or more of a rectangle, a triangle, a parallelogram, a trapezoid, and an arc.

11. The flexible display device according to claim 9, wherein a shape of the at least one protrusion is selected from one or more of a rectangle, a triangle, a parallelogram, a trapezoid, and an arc.

12. The flexible display device according to claim 9, wherein a plurality of grooves are disposed between all the two adjacent signal lines of the edge of the organic layer.

13. The flexible display device according to claim 12, wherein the plurality of grooves are evenly distributed along the edge of the organic layer in a direction of a length.

14. The flexible display device according to claim 9, wherein a plurality of protrusions are disposed between all the two adjacent signal lines of the edge of the organic layer.

15. The flexible display device according to claim 14, wherein the plurality of protrusions are evenly distributed along the edge of the organic layer in a direction of length.

16. The flexible display device according to claim 9, wherein the total length of the edge of the organic layer between any the two adjacent signal lines is greater than or equal to 20 μm.
